(19) United States
(12) Patent Application Publication
(10) Pub. No.: US 2002/0152610 A1
(43) Pub. Date: Oct. 24, 2002

(54) Electronic circuit device and method of production of the same

(75) Inventors: Kazuo Nishiyama, Kanagawa (JP); Yoshiyuki Yanagisawa, Kanagawa (JP); Toshiharu Yanagida, Tokyo (JP); Masashi Enda, Kanagawa (JP); Yoshitaka Yoshino, Tokyo (JP); Yuichi Takai, Tokyo (JP); Kiyoshi Hasegawa, Kanagawa (JP)

Correspondence Address: David R. Metzger, SONNENSCHEIN NATH & ROSENTHAL, Wacker Drive Station, Sears Tower, P.O. Box #061080, Chicago, IL, 60606-1080, US

(73) Assignee: SONY CORPORATION

(21) Appl. No.: 10/170,495

(22) Filed: Jun. 12, 2002

Related U.S. Application Data
(62) Division of application No. 09/594,781, filed on Jun. 16, 2000.

(30) Foreign Application Priority Data
Jun. 17, 1999 (JP) P11-170990

(51) Int. Cl. H05K 3/34; H05K 3/36

(52) U.S. Cl. 29/840; 29/830

(57) ABSTRACT

An electronic circuit device of a three-dimensional mounting mode capable of being produced by a simple method while suppressing the production costs and of a structure resistant to external stress, including first-mounting-board wiring portions formed on a first mounting board, first mounting parts mounted on the first mounting board, bumps formed on the first mounting board connecting to the first-mounting-board wiring portion, a protective layer formed covering the first mounting parts so that at least the portions near the tops of the bumps are exposed, a second mounting board stacked as an upper layer of the protective layer, second-mounting-board wiring portions formed on the second mounting board in order to connect to the bumps, and second mounting parts mounted connecting to the second-mounting-board wiring portions on the second mounting board at the surface of the second mounting board opposite to the protective layer side, and a method of production of the same.

### BACKGROUND OF THE INVENTION

1. Field of the Invention

The present invention relates to an electronic circuit device and a method of production of the same, more particularly relates to an electronic circuit device made to be compact and high in density and a method of production of the same.

2. Description of the Related Art

Demand for more compact, thinner, and lighter digital video cameras, digital cellular phones, laptop personal computers, and other portable electronic devices has been increasing steadily. To meet the demand, a 70% reduction in three years has been realized in recent VLSIs and other semiconductor devices. In accordance with this, research and development have been conducted on how to improve the packaging density of parts on a mounting board in an electronic circuit device comprised of a VLSI or other semiconductor device mounted on a board.

To improve the packing density of parts, it is necessary to increase the density of terminals at the time of mounting semiconductor devices. To attain this, as shown in FIG. 4, for example, the trend in the peripheral terminal mounting mode having terminals in a peripheral region of a package has been from dual inline packages (DIP) and other through hole mount devices (THD) inserting leads into through holes formed in a printed board to small outline J-leaded packages (SOJ), small outline (L-leaded) packages (SOP), quad flat (L-leaded) packages (QFP), tape carrier packages (TCP), and other surface mount devices (SMD) mounted by soldering lead terminals on the surface of a board.

As compared with the above peripheral terminal mounting mode, the area terminal mounting mode has been developed which forms terminals in areas on the lower surface of the package so as to facilitate the increase of the density of terminals. Development is proceeding from for example ball grid arrays (BGA) to chip size packages (CSP), also referred to as a fine pitch BGAs (FBGA), wherein the package size is reduced to almost the size of the semiconductor chip.

The important points of the above technique of high density mounting are how to make the mounted parts smaller, how to decrease the intervals between them, and how to make them easy to connect in form.

The peripheral terminal mounting mode where lead terminals project out from the peripheral region and the CSP and other modes of forming terminals in areas on the lower surface of a package are satisfactory in terms of the ease of mounting.

On the other hand, along with the increasing density and functions of semiconductor devices, the number of connection terminals has been increasing as well. Realization of higher packing density corresponding to the increase in the number of pins of semiconductor devices requires an increasingly finer pitch. Methods of bare-chip mounting such as the method of mounting a semiconductor chip in a bare-chip state by a wire-bonding (WB) method or a flip-chip (PC) method of mounting a pad opening side of a semiconductor chip facing the mounting board in the peripheral terminal mounting mode and the method of directly forming bumps on the pad opening side of the semiconductor chip and mounting by the flip-chip (PC) method in a bare-chip state in the area terminal mounting mode have come into note and are being actively developed.

The above CSP and bare-chip mounting methods and other mounting modes, however, are designed to maximum the packing density on a mounting board, that is, how to make the LSI parts smaller and how to decrease the intervals between parts. There are limits to how far the density can be increased by these methods.

Further, even if it were eventually possible to mount parts with no limit on their closeness, mounting would end up becoming extremely difficult and problems arise in how to arrange test terminals for 5 confirming the connections.

As will be understood from the example of the change from the peripheral terminal mounting mode to the area terminal mounting mode in the above related art, in order to realize a higher packing density while securing a certain connection pitch and maintaining ease of connection requires, as shown in FIG. 4, evolution to a three-dimensional mounting mode of mounting by stacking LSls and other parts is need.

FIG. 5A is a sectional view of an electronic circuit device of the above three-dimensional mounting mode, and FIG. 5B is an enlarged sectional view of X1 to X4 portions in FIG. 5A.

A mounting board 10a has formed buried wiring 11 inside it and has formed surface wiring (12a and 13a) as its two sides.

The mounting board 10a is also formed with through holes penetrating through it and is formed with through hole wiring 14 and through hole electrodes (15a, 16a) connecting them.

Protective boards (10b, 10c) are formed on the two surfaces of the mounting board 10a covering the surface wiring (12a, 13a) and the through hole electrodes (15a, 16a). Openings reaching the surface wiring (12a, 13a) and through hole electrodes (15a, 16a) are formed at necessary portions.

Surface wiring (12b, 13b) respectively connecting to the surface wiring (12a, 13a) are formed, and through hole electrodes (15b, 16b) respectively connecting to the through hole electrodes (15a, 16a) are formed.

A semiconductor chip 20 is connected and mounted via the bumps 21 to the surface wiring 12b and through hole electrodes 15b formed on one surface of the board. Further, resistors, capacitors, and other general electronic parts 37 are mounted at other portions.

A semiconductor ship 20 is connecting and mounted via the bumps 21 to the surface wiring 13b and through hole electrodes 16b on the other surface of the board as well. Resistors, capacitors, and other general electronic parts 37 are mounted at other portions.

On one surface of the substrate, as shown in FIG. 5B, semiconductor mounting parts X1 to X4 formed with first bumps 42 and second bumps 43 so as to connect to wiring 41 formed buried in sub-boards 40 and formed with semiconductor ships 44 connected to the first bumps 42 are mounted stacked with the second bumps 43 and the wiring 41 mutually connected.

In the electronic circuit device of a three-dimensional mounting mode shown in FIGS. 5A and 5B, however, there are the disadvantages that the mounting height becomes higher by the amount of stacking of semiconductor mounting parts, there is susceptibility to mechanical or environmental stress from the outside, and, in some cases, junction breakdown easily occurs at bump connection portions etc.

As an electronic circuit device of a three-dimensional mounting mode to solve the above problems, Japanese Unexamined Patent Publication (Kokai) No. 6-120670 discloses a mounting method consisting of burying mounting parts in openings of a first mounting board being formed with the openings in advance and stacking second mounting boards on the upper and lower surfaces thereof. However, this method requires the formation of openings in advance in the first mounting board and is otherwise extremely complicated, so the production costs becomes high and it is difficult to put this method into practical use.

### SUMMARY OF THE INVENTION

An object of the present invention is to provide an electronic circuit device of a three-dimensional mounting mode capable of being produced by a simple method while suppressing the production costs and of a structure resistant to external stress and a method of production of the same.

To attain the above object, according to a first aspect of the present invention, there is provided an electronic circuit device comprising a first mounting board; a first-mounting-board wiring portion formed in the first mounting board; a first mounting part mounted on the first mounting board connected to the first-mounting-board wiring portion; bumps formed on the first mounting board connected to the first-mounting-board wiring portion; a protective layer formed covering the first mounting part so that at least portions near the tops of the bumps are exposed; a second mounting board stacked at an upper layer of the protective layer; a second-mounting-board wiring portion formed in the second mounting board connecting to the bumps; and a second mounting part mounted on the second mounting board at the surface of the second mounting portion opposite to the protective layer and connecting to the second-mounting-board wiring portion.

Preferably, the bumps are formed higher than the height of the first mounting part after mounting.

Preferably, the second-mounting-board wiring portion includes a wiring portion penetrating through the second mounting board.

Preferably, the protective layer is a resin layer.

Preferably, the first-mounting-board wiring portion includes a buried wiring portion formed in the first mounting board.

More preferably, the buried wiring portion includes a wiring portion penetrating through the first mounting board.

Preferably, the bumps and the second-mounting-board wiring portion are connected through an anisotropic conductive layer.

More preferably, the anisotropic conductive layer includes at least an anisotropic conductive film or an anisotropic conductive paste.

That is, the electronic circuit device of the present invention comprises a first mounting board having first-mounting-board wiring portion on which a first mounting part is mounted connected to the first-mounting-board wiring portion. Here, the first-mounting-board wiring portion comprises a buried wiring portion formed for example inside the first mounting board and including a wiring portion penetrating through the first mounting board.

On the first mounting board, bumps higher than the height of the first mounting board after mounting are formed connecting to the above first-mounting-board wiring portion, a protective layer such as a sealing resin layer is further formed so that at least portions near the tops of the bumps are exposed, and a second mounting board is stacked as an upper layer thereon.

Furthermore, the second mounting board is formed with a second-mounting-board wiring portion including a wiring portion penetrating through the second mounting board so as to be connected to the bumps via an anisotropic conductive layer such as an anisotropic conductive film or anisotropic conductive paste. On the second mounting board at the surface of the second mounting board opposite to the protective layer side is mounted a second mounting part connecting to the second-mounting-board wiring portion.

The electronic circuit device of the present invention is therefore an electronic circuit device of a three-dimensional mounting mode structured to be resistant to stress from the outside. It does not require a board formed with openings in advance, so can be produced by a simple method while suppressing the production costs.

According to a second aspect of the present invention, there is provided a method of producing an electronic circuit device, including the steps of mounting a first mounting part on a first mounting board having a first-mounting-board wiring portion so as to connect to the first-mounting-board wiring portion; forming bumps on the first mounting board so as to connect to the first-mounting-board wiring portion; forming a protective layer covering the first mounting part so that at least portions near the tops of the bumps are exposed; stacking a second mounting board having a second-mounting-board wiring portion at an upper layer of the protective layer so that the second-mounting-board wiring portion and the bumps are connected; and mounting a second mounting part on the second mounting board at the surface of the second mounting board opposite to the protective layer side so as to connect to the second-mounting-board wiring portion.

Preferably, the step of forming the bumps forms bumps higher than the height of the first mounting part after mounting.

Preferably, the step of forming bumps forms bumps by continuously dropping molten solder on the first mounting board so as to connect to the first-mounting-board wiring portion.

Preferably, the step of forming the protective layer includes a step of forming a protective layer covering the first mounting part and a step of polishing an upper surface of the protective layer until at least the portions near the tops of the bumps are exposed.

Preferably, a second-mounting-board wiring portion including a wiring portion penetrating through the second mounting board is used as the second-mounting-board wiring portion.

Preferably, a sealing resin layer is formed as the protective layer.

Preferably, a first-mounting-board wiring portion including a buried wiring portion penetrating through the first mounting board is used as the first-mounting-board wiring portion.

More preferably, a buried wiring portion including a wiring portion penetrating through the first mounting board is used as the buried wiring portion.

Preferably, the method further includes, after the step of forming the protective layer and before the step stacking the second-mounting-board at the upper layer of the protective layer, a step of forming at least an anisotropic conductive layer at an upper layer of the protective layer, wherein the step of stacking the second-mounting-board at the upper layer of the protective layer stacks the board so that the bumps and the second-mounting-board wiring portion are connected through the anisotropic conductive layer.

More preferably, the step of forming the anisotropic conductive layer stacks at least an anisotropic conductive film or an anisotropic conductive paste.

Preferably, the method further includes, after the step of mounting the first mounting part on, the first mounting board and before the step of forming the protective layer, a step of sealing a gap between the first mounting board and the first mounting part with resin.

That is, the method of production of the electronic circuit device of the present invention mounts on a first mounting board having a first-mounting-board wiring portion a first mounting part so as to connect to the first-mounting-board wiring portion and seals a space between the first mounting board and the first mounting part with resin. Here, the first-mounting-board wiring portion for example uses a wiring portion having a buried wiring portion formed in the first mounting board and including a wiring portion penetrating through the first mounting board.

Next, bumps are formed on the first mounting board by for example continuously dropping molten solder so that the height becomes higher than that of after mounting the first mounting part and to connect to the first-mounting-board wiring portion.

Next, a protective layer such as a sealing resin formed covering the first mounting part and is polished from the upper surface until at least the 5 portions near the tops of the bumps are exposed.

Next, the second mounting board having the second-mounting-board wiring portion is stacked on the protective layer so that the second-mounting-board wiring portion and the bumps are connected via an anisotropic conductive layer such as an anisotropic conductive film or anisotropic conductive paste. Here, the second-mounting-board wiring portion uses for example a wiring portion including a wiring portion penetrating through the second mounting plate.

Next, the second mounting part is mounted on the second mounting board at the surface of the second mounting board opposite to the protective layer side so as to connect to the second-mounting-board wiring portion.

According to the above method of production of an electronic circuit device of the present invention, a mounting board formed with openings in advance becomes unnecessary and an electronic circuit device of a three-dimensional mounting mode configured to be resistant to external stress can be produced by a simple method while suppressing the production costs:

### BRIEF DESCRIPTION OF THE DRAWINGS

These and other objects and features of the present invention will become clearer from the following description of the preferred embodiments given with reference to the accompanying drawings, in which:

FIG. 1 is a sectional view of an electronic circuit device according to an embodiment;

FIG. 2A to FIG. 2H are sectional views of steps of a method of production of an electronic circuit device according to the embodiment, wherein FIG. 2A is a view up to a step of forming a first-mounting-board wiring portion, FIG. 2B is a view up to a step of mounting first mounting parts, FIG. 2C is a view up to a step of filling a resin in a space between the first mounting parts and the first mounting board, FIG. 2D is a view up to a step of forming bumps, FIG. 2E is a view up to a step of forming a protective layer, FIG. 2F is a view up to a step of polishing, FIG. 2G is a view up to a step of stacking a second mounting board, and FIG. 2H is a view up to a step of mounting second mounting parts;

FIG. 3A to 3C are schematic views for explaining a method of forming solder bumps by a metal jet method; 25 FIG. 4 is a schematic view of trends in high density mounting in electronic circuit devices; and

FIG. 5A and FIG. 5B are sectional views of an electronic circuit device according to the related art, wherein FIG. 5B is an enlarged sectional view of X1 to X4 in FIG. 5A.

### DESCRIPTION OF THE PREFERRED EMBODIMENTS

Below, preferred embodiments of an electronic circuit device and the method of production of the present invention will be described with reference to the accompanying drawings.

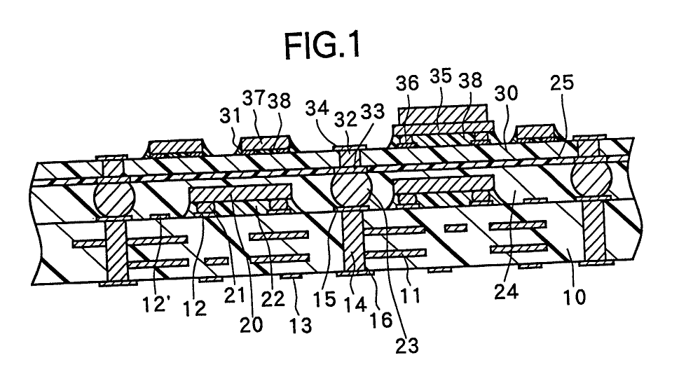

FIG. 1 is a sectional view of an electronic circuit device according to the present embodiment.

Buried wiring 11 is formed inside a first mounting board 10, while surface wirings (12, 13) are formed on the two sides of the first mounting board 10. Here, the surface wiring includes test terminals 12′ for confirming connection of mounting parts.

Also, through holes are formed penetrating through the first mounting board 10. Further, through hole wiring 14 and through hole electrodes (15, 16) connected thereto are formed.

As explained above, a first-mounting-board wiring portion is comprised by the buried wiring 11, surface wiring (12, 13), through hole wiring 14, and through hole electrodes (15, 16) and so on.

A semiconductor chip (first mounting part) 20 connected to the surface wiring 12 etc. formed on one surface of the first mounting board 10 is mounted connected via the bumps 21 composed of solder etc. The space between the semiconductor chip 20 and the first mounting board 10 is sealed by a sealing resin layer 22.

Furthermore, bumps 23 composed of solder are formed connecting to the through hole electrodes 15 etc. formed on one surface of the first mounting board 10. The bumps 23 are formed so that they become higher in height than that after mounting the semiconductor chip 20.

Here, a protective layer 24 of a sealing resin layer etc. Is formed by covering the semiconductor chip 20 so that at least the portions near the tops of the bumps 23 are exposed.

An anisotropic conductive layer 25 such as an anisotropic conductive film or an anisotropic conductive paste is stacked as an upper layer of the protective layer 24. The second mounting board 30 is stacked thereon.

Here, the anisotropic conductive film is comprised of an insulating resin in which fine conductive balls are dispersed and processed to a film shape. The film itself is insulating but when it is squeezed by being sandwiched between a pair of electrodes, the conductive balls contact the pair of electrodes and electrically connect and bond the two electrodes. The anisotropic conductive paste is a paste of an insulating resin in which fine conductive balls are dispersed. An anisotropic conductive film formed by applying the paste has the same effect as the above anisotropic conductive film.

A second-mounting-board wiring portion is formed by surface wiring 31 formed on one or both surfaces of the second mounting board 30, through hole wiring 32 passed through the through holes formed penetrating through the second mounting board 30, through hole electrodes (33, 34) connected thereto, etc.

The through hole electrode 33 etc. at the second-board wiring portion squeezes the anisotropic conductive layer 25 such as an anisotropic conductive film or anisotropic conductive paste and connects to the bumps 23 via the conductive balls in the anisotropic conductive layer 25.

Furthermore, on the second mounting board 30 at the surface of the second mounting board 30 opposite to the protective layer 24 are mounted as the second mounting parts, a semiconductor chip 35 via the bumps 36 composed of solder etc., or resistors, capacitors, or other general electronic parts 37 directly connecting to the surface wiring 31 of the second-mounting-wiring portion etc.

The above electronic circuit device of the present embodiment is an electronic circuit device of a three-dimensional mounting mode having a configuration resistant to stress from the outside and ensuring reliability of high packing density. The configuration does not require a board formed with openings in advance and can be produced by a simple method suppressing production costs.

The three-dimensional mounting mode enables to layout by wiring of the shortest connection wiring length and to realize a mounting mode applicable to a high speed and high frequency due to reduction of wiring resistance 15 loss.

Next, a method of production of the electronic circuit device according to the above present embodiment will be explained with reference to the drawings.

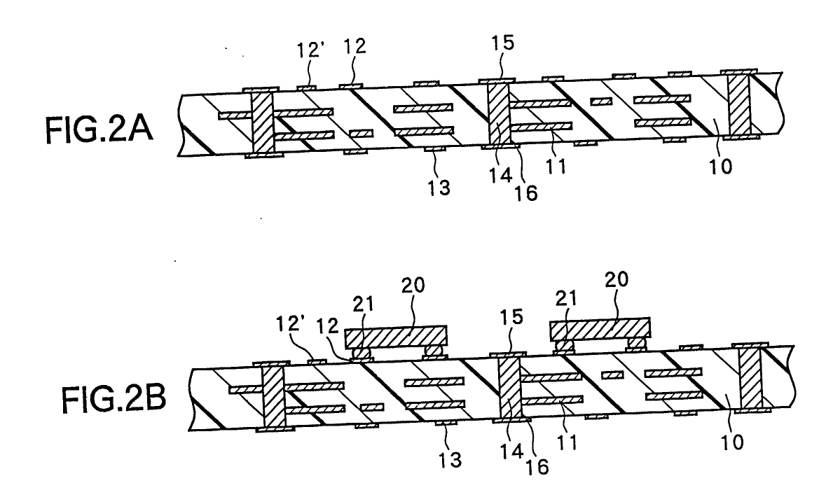

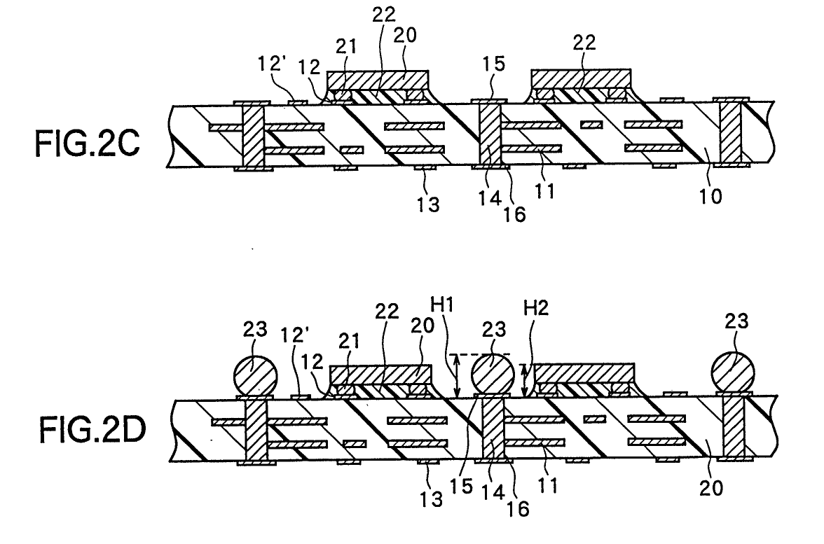

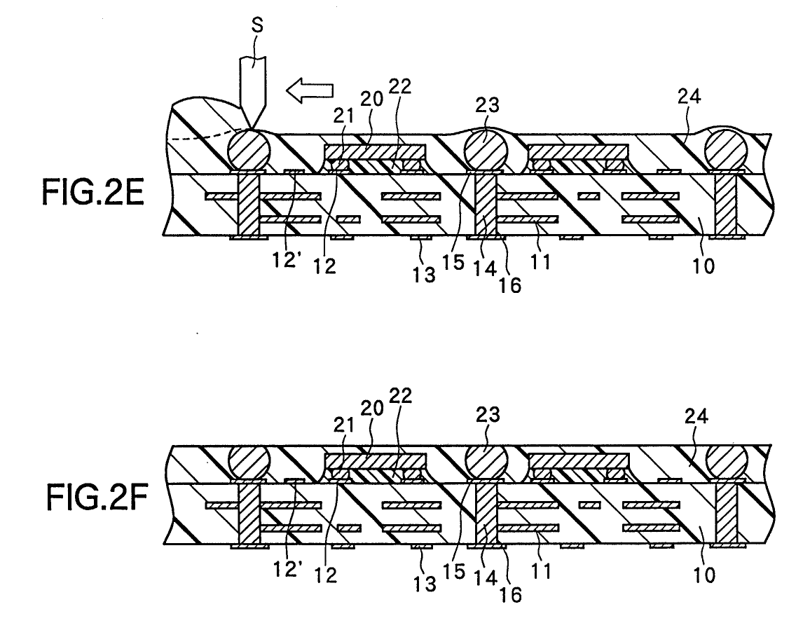

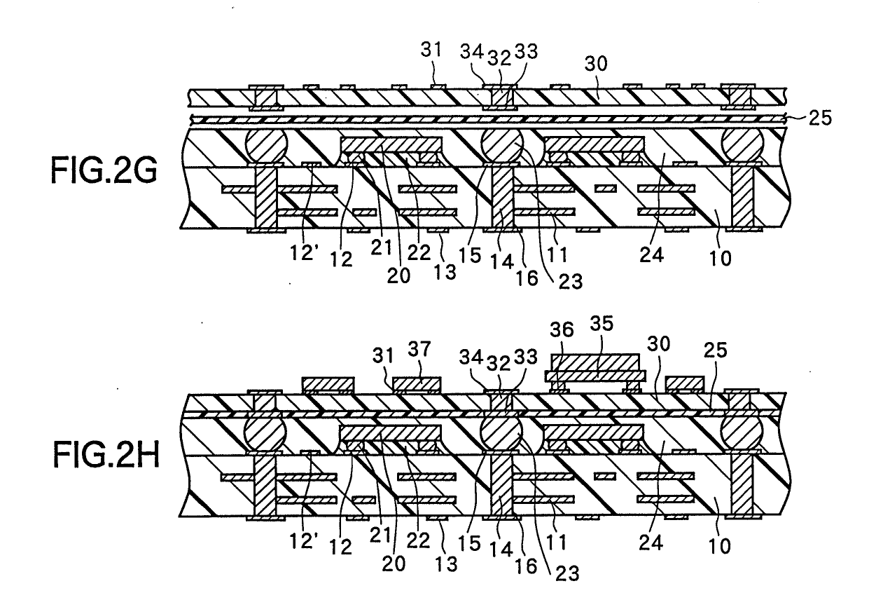

First, as shown in FIG. 2A, the first mounting board formed with buried wiring 11 therein. On both surfaces of the first mounting board 10 are formed surface wirings (12, 13) including test terminals 12′ for confirming connection of mounting parts.

Furthermore, through holes are formed penetrating through the first mounting board 10. Through hole wiring 14 and through hole electrodes (15, 16) connecting thereto are formed.

As explained above, a first-mounting-board wiring portion comprised of the buried wiring 11, surface wiring (12, 13), through hole wiring 14, and through hole electrodes (15, 16) etc. is formed.

Next, as shown in FIG. 2B, a semiconductor chip (first mounting part) 20 formed with bumps 21 composed of solder etc. are mounted connecting to the surface wiring 12 etc. formed on one surface of the above first mounting board 10.

By making the thickness of the above semiconductor chip 20 thinner to the limit, the thickness of the overall board can be suppressed even when the semiconductor chip is buried. For example, by making the thickness of the semiconductor chip not more than 0.1 mm, the height of the semiconductor chip after mounting can be suppressed to be not more than 0.2 mm.

At this time, when examining connection conditions of semiconductor chips 20 by using test terminals 12′ for confirming the connection of the mounting parts and confirming poor connection, it is possible to exchange poor semiconductor chips 20 and thereby mount only good chips.

Next, as shown in FIG. 2C, by filling a resin in a space between the semiconductor chip 20 and the first mounting board 10 by a not shown dispenser etc. and applying annealing or other curing treatment, a sealing resin layer 22 is formed.

By forming the sealing resin layer 22, the reliability of connection of a semiconductor chip 20 can be improved.

Next, as shown in FIG. 2D, bumps 23 are formed connecting to the through hole electrode 15 etc. formed on one surface of the first mounting board by transfer of solder balls etc.

Here, the height HI of the bumps 23 is set to be higher than the height H2 of a semiconductor chip 20 after mounting, for example, when the height H2 of the semiconductor chip 20 after mounting is not more than 0.2 mm, solder balls etc. having a diameter of 0.25 to 0.3 mm are used.

Next, as shown in FIG. 2E, by supplying an epoxy resin etc. to cover the semiconductor chip 20 and the bumps 23 by for example a printing method, a protective layer 24 for sealing the semiconductor chip 20 etc. with resin is formed.

At this time, a somewhat larger quantity of epoxy resin is supplied, excess resin is removed by a squeegee S, and heat treatment of for example 150 to 200° C. is performed for curing.

By using the above protective layer to seal with resin the semiconductor circuit device and the base portion of the bumps 23, the reliability of connection of the semiconductor chip 20 and the bumps 23 can be improved.

Next, as shown in FIG. 2F, the protective layer 24 is polished until at least the portions near the tops of the bumps are exposed.

From the above, the protective layer 24 can be formed covering the first mounting part so that at least the portions near the tops of the bumps are exposed while securing the flatness of the protective layer 24.

Next, as shown in FIG. 2G, for example, an anisotropic conductive film 25 such as an anisotropic conductive film or anisotropic conductive paste is stacked as an upper layer of the protective layer 24 and a second mounting board 30 is further stacked thereon.

Here, on the second mounting board 30, a second-mounting-board wiring portion comprised by surface wiring 31 formed on one or both surfaces of the second mounting board 30, through hole wiring 32 passed through the through holes formed penetrating through the second mounting board 30, through hole electrodes (33, 34) connected thereto, etc. is formed arranged to be in register with the positions of the bumps 23. By crushing and heat bonding the anisotropic conductive layer 25 such as the anisotropic conductive film or anisotropic conductive paste, the through hole electrodes 33 etc. of the second-mounting-board wiring portion and the bumps 23 are connected via the conductive balls in the anisotropic conductive layer 25 and the second mounting board 30 is adhered by the anisotropic conductive film 25. As a result, the first-mounting-board wiring portion of the first mounting board and the second-mounting-board wiring portion of the second mounting board 30 are connected.

Next, as shown in FIG. 2H, a semiconductor chip 35 formed with bumps 36 composed of solder etc. or resistors, capacitors, or other general electronic parts 37 are mounted as the second mounting parts on the second mounting board 30 at the surface of the second mounting board 30 opposite to the protective layer 24 side connected to the surface wiring 31 etc. of the second-mounting-board wiring portion.

Next, resin is supplied to a space between the semiconductor chip 35 and the second mounting board 30 or a space between the general electronic parts 37 etc. and the second mounting board 30 by a not shown dispenser etc. Annealing or other curing is performed to form the sealing resin layer 38 and complete the electronic circuit device shown in FIG. 1.

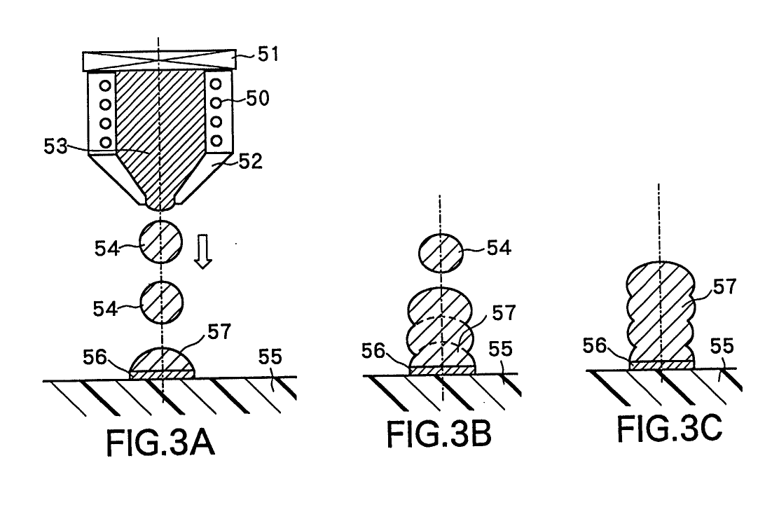

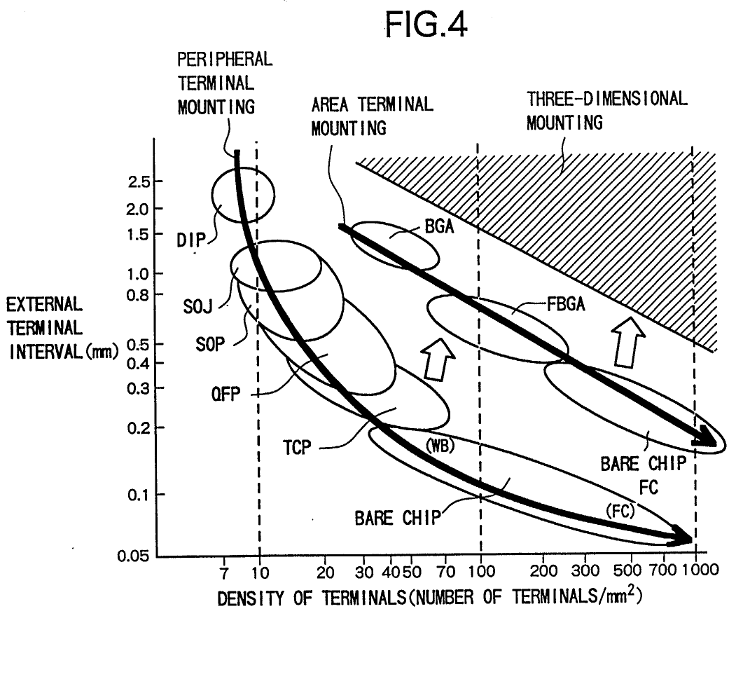

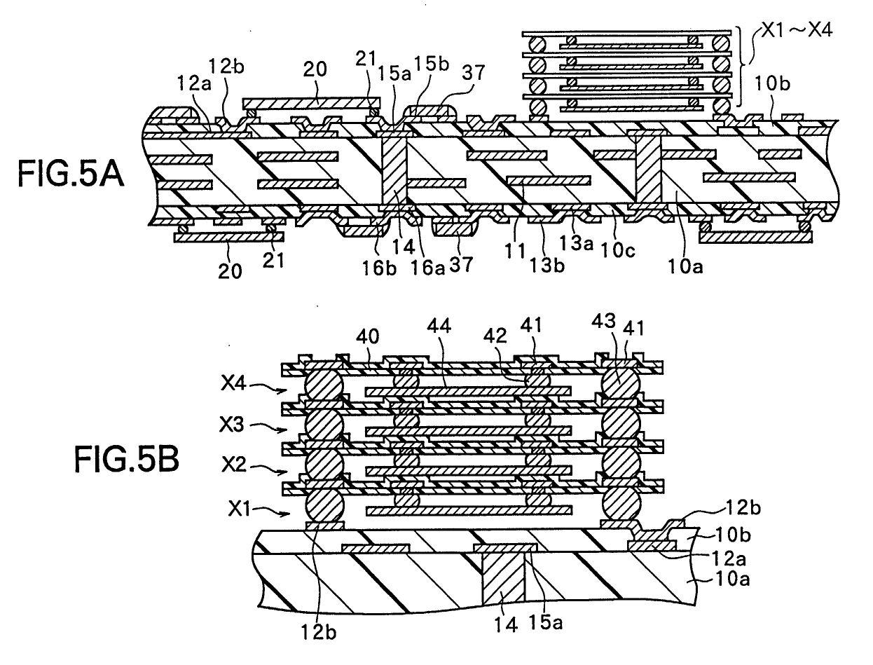

As the method of forming the above bumps 23, for example, a metal jet method shown in FIGS. 3A to 3C may be used.

In the above method, for example as shown in FIG. 3A, solder 53 heated by a heater 50 to make it molten is stored in a solder dropper 52 with a built-in heater 50 and piezoelectric oscillator 51. By causing the piazo oscillator 51 to oscillator at this time, drops of molten solder 54 drop from the tip of the solder dropper 52 to the electrodes 56 on the board 55. The molten solder drops 54 cool as they drop and hardened on the electrodes 56 to form bumps 57.

Here, by continuously dropping the molten solder drops 54 as shown in FIG. 3A, the molten solder drops 54 pile up as shown in FIG. 3B so that finally a solder bump 57 having a small diameter and a high aspect ratio can be formed as shown in FIG. 3C.

According to the method of production of the electronic circuit device of the present embodiment, a board formed with openings in advance is not necessary and it is possible to produce an electronic circuit device of a three-dimensional mounting mode having a configuration resistant to stress from the outside and ensuring the reliability of high density mounting can be produced by a simple method while suppressing the production costs.

The mounting part to be mounted on the electronic circuit device of the present invention may be of any kind such as an MOS transistor type semiconductor device, a bipolar type semiconductor device, BiCMOS type semiconductor device, a semiconductor device mounting a logic and memory, etc.

The electronic circuit device and the method of production of the present invention are not limited to the above embodiments.

For example, as mounting parts buried in the protective layer between the first mounting board and the second mounting board, resistors, capacitors, and other general electronic parts can be mounted other than semiconductor chips.

Also, the materials comprising the mounting boards, wiring layers, bumps, sealing resin, protective layers, etc. are not specifically limited. Materials other than those described in the above embodiments may be used.

A variety of modifications can be made within the scope of the present invention.

Summarizing the effect of the invention, as explained above, according to the present invention, there is provided an electronic circuit device of a three-dimensional mounting mode which does not require a board formed with openings in advance and able to be produced by a simple method while suppressing the production costs.

Also, according to the method of production of the electronic circuit device of the present invention, an electronic circuit device of the present invention can be easily produced, a board formed with openings in advance is not necessary, and an electronic circuit device of a three-dimensional mounting mode configured to be resistant to stress from the outside can be produced by a simple method while suppressing the production costs.

While the invention has been described with reference to specific embodiment chosen for purpose of illustration, it should be apparent that numerous modifications could be made thereto by those skilled in the art without departing from the basic concept and scope of the invention.

What is claimed is:

1. A method of producing an electronic circuit device, including the steps of:
mounting a first mounting part on a first mounting board having a first-mounting-board wiring portion so as to connect to the first-mounting-board wiring portion;
forming bumps on the first mounting board so as to connect to the first-mounting-board wiring portion;
forming a protective layer covering the first mounting part so that at least portions near the tops of the bumps are exposed;
stacking a second mounting board having a second-mounting-board wiring portion at an upper layer of the protective layer so that the second-mounting-board wiring portion and the bumps are connected; and
mounting a second mounting part on the second mounting board at the surface of the second mounting board opposite to the protective layer side so as to connect to the second-mounting-board wiring portion.

2. A method of producing an electronic circuit device as set forth in claim 1, wherein the step of forming the bumps forms bumps higher than the height of the first mounting part after mounting.

3. A method of producing an electronic circuit device as set forth in claim 1, wherein the step of forming bumps forms bumps by continuously dropping molten solder on the first mounting board so as to connect to the first-mounting-board wiring portion.

4. A method of producing an electronic circuit device as set forth in claim 1, wherein the step of forming the protective layer includes a step of forming a protective layer covering the first mounting part and a step of polishing an upper surface of the protective layer until at least the portions near the tops of the bumps are exposed.

5. A method of producing an electronic circuit device as set forth in claim 1, wherein a second-mounting-board wiring portion including a wiring portion penetrating through the second mounting board is used as the second-mounting-board wiring portion.

6. A method of producing an electronic circuit device as set forth in claim 1, wherein a sealing resin layer is formed as the protective layer.

7. A method of producing an electronic circuit device as set forth in claim 1, wherein a first-mounting-board wiring portion including a buried wiring portion penetrating through the first mounting board is used as the first-mounting-board wiring portion.

8. A method of producing an electronic circuit device as set forth in claim 7, wherein a buried wiring portion including a wiring portion penetrating through the first mounting board is used as the buried wiring portion.

9. A method of producing an electronic circuit device as set forth in claim 1,
further including, after the step of forming the protective layer and before the step of stacking the second-mounting-board at the upper layer of the protective layer, a step of forming at least an anisotropic conductive layer at an upper layer of the protective layer, wherein
the step of stacking the second-mounting-board at the upper layer of the protective layer stacks the board so that the bumps and the second-mounting-board wiring portion are connected through the anisotropic conductive layer.

10. A method of producing an electronic circuit device as set forth in claim 9, wherein the step of forming the anisotropic conductive layer stacks at least an anisotropic conductive film or an anisotropic conductive paste.

11. A method of producing an electronic circuit device as set forth in claim 1, further including, after the step of mounting the first mounting part on the first mounting board and before the step of forming the protective layer, a step of sealing a gap between the first mounting board and the first mounting part with resin.

12. A method of producing an electronic circuit device, including the steps of:
mounting a first mounting part on a first mounting board having a first-mounting-board wiring portion so as to connect to the first-mounting-board wiring portion;
forming bumps on the first mounting board so as to connect to the first-mounting-board wiring portion;
forming a protective layer covering the first mounting part and the bumps so that at least portions near the tops of the bumps are exposed;
stacking a second mounting board having a second-mounting-board wiring portion at an upper layer of the protective layer so that the second-mounting-board wiring portion and the bumps are connected; and
mounting a second mounting part on the second mounting board at the surface of the second mounting board opposite to the protective layer side so as to connect to the second-mounting-board wiring portion.

13. A method of producing an electronic circuit device, including the steps of:
mounting a first mounting part on a top surface of a first mounting board having a first-mounting-board wiring portion so as to connect to the first-mounting-board wiring portion;
forming a first protective layer between the first mounting board and the first mounting part;
forming bumps on only the top surface of the first mounting board so as to connect to the first-mounting-board wiring portion;
forming a second protective layer covering the first mounting part and the bumps so that at least portions near the top of the bumps are exposed;
stacking a second mounting board having a second-mounting-board wiring portion at an upper layer of the protective layer so that the second-mounting-board wiring portion and the bumps are connected; and
mounting a second mounting part on the second mounting board at the surface of the second mounting board opposite to the protective layer side so as to connect to the second-mounting-board wiring portion.

14. A method of producing an electronic circuit device, including the steps of:
mounting a first mounting part on a top surface of a first mounting board having a first-mounting-board wiring portion so as to connect to the first-mounting-board wiring portion;
forming a first protective layer between the first mounting board and the first mounting part;
forming bumps on only the top surface of the first mounting board so as to connect to the first-mounting-board wiring portion;
forming a second protective layer covering the first mounting part and the bumps;
removing an upper portion of the second protective layer so that at least portions near the top of the bumps are exposed;
stacking a second mounting board having a second-mounting-board wiring portion at an upper layer of the protective layer so that the second-mounting-board wiring portion and the bumps are connected; and
mounting a second mounting part on the second mounting board at the surface of the second mounting board opposite to the protective layer side so as to connect to the second-mounting-board wiring portion.
